(19) United States
(12) Patent Application Publication
(10) Pub. No.: US 2026/0214844 A1
(43) Pub. Date: Jul. 23, 2026

(54) IMMERSION COOLING FOR ELECTRONIC DEVICES

(71) Applicant: ROSSEAU GROUP INTERNATIONAL INC., Markham (CA)

(72) Inventor: Richard MARGERISON, Georgetown, TX (US)

(21) Appl. No.: 19/143,208

(22) PCT Filed: Dec. 28, 2023
(86) PCT No.: PCT/CA2023/051769

§ 371 Date: Jun. 25, 2025

Related U.S. Application Data
(60) Provisional application No. 63/435,942, filed on Dec. 29, 2022.

(51) Int. Cl. H05K 7/20

(52) U.S. Cl. CPC H05K 7/20272; H05K 7/20236

(57) ABSTRACT

Disclosed herein are tanks for immersion cooling electronic devices. The tank includes an intake disposed proximate a bottom surface of the tank, the intake including at least one inlet for dispensing cooling liquid into the tank; and an outtake defined by a lip extending proximate a top wall of the tank, whereby the cooling liquid exits the tank by flowing over the lip; and wherein the at least one inlet is oriented downwardly such that the cooling liquid dispensed therethrough initially flows downward towards the bottom surface of the tank before flowing upward past at least one electronic device disposed in the tank. Also disclosed herein are methods of immersion cooling of electronic devices. Also disclosed herein are hangers for hanging an electronic device in an immersion cooling tank.

### CROSS-REFERENCE TO RELATED APPLICATIONS

This application claims all benefit including priority to U.S. Provisional Patent Application 63/435,942, filed Dec. 29, 2022, and entitled “IMMERSION COOLING FOR ELECTRONIC DEVICES”; the entire contents of which are hereby incorporated by reference herein.

### FIELD

This disclosure relates to immersion cooling of electronic devices.

### BACKGROUND

As electronic devices (e.g., computing devices such as servers, cryptocurrency miners, etc., as well as networking devices and data storage devices connected thereto) function, some of the electricity drawn thereby is converted into heat, which tends to increase the temperature of the devices over time. In absence of suitable cooling, the devices may heat up to temperatures outside of desired operating ranges, thus rendering them to less efficient operation, shutdown, malfunction or even damage. Various cooling approaches may be used to actively keep the computers from overheating. For instance, using immersion cooling, electronic devices are submerged in a tank filled with a liquid that is thermally-conductive yet electrically non-conductive. By replacing heated liquid with cooler liquid inside the tank at a suitable rate, regulation of the temperature of the electronic devices within a desired operating range may be achieved.

However, when implemented in data centers or other high-density computing facilities, typical immersion cooling systems present efficiency and operational challenges, as servicing, addition, removal and/or reconfiguring of computers inside a given tank frequently occurs.

### SUMMARY

According to an aspect, there is provided a tank for immersion cooling of electronic devices. The tank includes an intake disposed proximate a bottom surface of the tank, the intake including at least one inlet for dispensing cooling liquid into the tank; and; an outtake defined by a lip extending proximate a top wall of the tank, whereby the cooling liquid exits the tank by flowing over the lip; and wherein the at least one inlet is oriented downwardly such that the cooling liquid dispensed therethrough initially flows downward towards the bottom surface of the tank before flowing upward past at least one electronic device disposed in the tank.

In such tank, the intake may be configured to provide a pressurized stream of cooling liquid at a downward angle through the inlet.

In such tank, the downward angle may be between approximately 20-90 degrees relative to the bottom surface of the tank.

In such tank, the downward angle may be between approximately 30-70 degrees relative to a bottom surface of the tank.

In such tank, the downward angle may be approximately 90 degrees relative to the bottom surface of the tank.

In such tank, the cooling liquid dispensed through the at least one inlet may spread across at least a portion of the bottom surface of the tank.

In such tank, the at least one inlet may include a plurality of inlets.

In such tank, the plurality of inlets may be substantially evenly spaced from one another.

In such tank, the intake may be configured to cause the cooling liquid to be dispensed through each of the plurality of inlets with substantially similar pressure.

In such tank, the intake may include a first end and a second end, the ends proximate respective end walls of the tank.

In such tank, the at least one inlet may be oriented to dispense the cooling liquid in a direction parallel to at least one of the end walls.

In such tank, each of the first end and the second end may be in fluid communication with an intake feed that urges the cooling liquid into that end.

In such tank, the cooling liquid urged into the first end of the intake may converge with the cooling liquid urged into the second end of the intake.

Such tank may be configured to suspend the at least one electronic device above the bottom surface of the tank.

According to another aspect, there is provided an immersion cooling system for electronic devices. The system includes a first tank as provided above, and a second tank as provided above, wherein the first and second tanks are oriented such that the lip of the first tank and the lip of the second tank are substantially parallel and meet at a trough extending between the tanks, and the cooling liquid flowing over the lips is received in the trough.

In such immersion cooling system, the trough may slope in a direction substantially parallel to the lips of the first and second tanks.

According to yet another aspect, there is provided a method for immersion cooling of electronic devices. The method includes suspending at least one electronic device above a bottom surface of a tank for containing cooling fluid; and dispensing the cooling fluid into the tank from an intake disposed proximate the bottom surface of the tank; and wherein the cooling fluid is dispensed downwardly such that the cooling liquid flows towards the bottom surface of the tank before flowing upward past the at least one electrical device and out of the tank.

Such method may further include sliding the at least one electronic device to adjust its horizontal position in the tank without removing the at least one electronic device from the tank.

According to a further aspect, there is provided an immersion cooling system for electronic devices. The system includes: a tank including: an intake for dispensing a cooling liquid into a bottom of the tank; and an outtake defined by a lip extending horizontally proximate a top of the tank, whereby the cooling liquid exits the tank by flowing over the lip; and a plurality of hangers, each for suspending an electronic device into the tank to be immersed in the cooling liquid, each of the hangers including: an arm for extending into the tank, the arm having a length for hanging the electronic device at a desired vertical position above the bottom of the tank; and a mount for slidably resting on or above the lip to hang at least one of the electronic devices at a desired horizontal position in the tank.

In such immersion cooling system, the lip may extend horizontally along a top of a first side wall of the tank.

In such immersion cooling system, the mount is a first mount, and at least one of the hangers may include a second mount for slidably resting along a top of a second side wall of the tank opposite the first side wall.

In such immersion cooling system, the second mount may be disposed on the hanger higher than the first mount.

In such immersion cooling system, the mount may form a v-shape for engage a slope of the lip.

In such immersion cooling system, at least one of the plurality of hangers may include a bracket for removably mounting the electronic device.

In such immersion cooling system, the plurality of hangers may include a first hanger and a second hanger, and the length of the arm of the first hanger differs from the length of the arm of the second hanger.

In such immersion cooling system, the plurality of hangers may include a first hanger and a second hanger, and the width of the first hanger differs from the width of the second hanger.

In such immersion cooling system, the plurality of hangers may include a first hanger with a mount for mounting a given number of electronic devices; and a second hanger with a mount for mounting another given number of electronic devices greater than the given number of the first hanger.

In such immersion cooling system, at least one of the hangers may include a grip for a user to grip the hanger when lifting the hanger from a resting position on the tank.

According to yet a further aspect, there is provided a hanger for hanging an electronic device in an immersion cooling tank. The hanger includes: an arm for extending into the immersion cooling tank, the arm having a length for suspending a mounted electronic device at a desired vertical position above the bottom of the tank; a first mount for slidably resting on or above a lip of the tank extending horizontally along a first side wall of the tank, the lip defining an outtake for cooling liquid to exit the tank by flowing over the lip; and a second mount for slidably resting on a second sidewall of the tank opposite the first side wall, the second mount disposed higher than the first mount.

In such hanger, the first mount may form a v-shape for engage a downward slope of the lip.

Such hanger may further include a bracket for removably mounting the electronic device.

Other features will become apparent from the drawings in conjunction with the following description.

### BRIEF DESCRIPTION OF DRAWINGS

In the figures which illustrate example embodiments,

FIG. 1 is a perspective view of a tank for immersion cooling of electronic devices, in accordance with an embodiment;

FIG. 2 is a top view of the tank of FIG. 1;

FIG. 3 is a cut-away front elevation view of the tank of FIG. 1;

FIG. 4A is a cut-away side elevation view of the tank of FIG. 1;

FIG. 4B is a cut-away side elevation view of a tank, in accordance with another embodiment;

FIG. 5 is a perspective view of a hanger for hanging electronic devices into a tank for immersion cooling, in accordance with an embodiment;

FIG. 6 is a top view of the hanger of FIG. 5;

FIG. 7 is a side elevation of view of the hanger of FIG. 5;

FIG. 8 and FIG. 9 are each a perspective view of a plurality of hangers of various sizes and configurations, in accordance with embodiments;

FIG. 10 is a perspective view of a hanger with adjustable length arms, in accordance with an embodiment;

FIG. 11 and FIG. 12 each depict electronic devices mountable to a hanger, in accordance with an embodiment;

FIG. 13 depicts an electronic device mounted to a hanger, in accordance with an embodiment;

FIG. 14 is a perspective view of an intake of the tank of FIG. 1;

FIG. 15 is a side schematic view of the intake of FIG. 14;

FIG. 16 is a top plan view of the intake of FIG. 14;

FIG. 17A and FIG. 17B each is a side schematic view of an intake, each in accordance with a respective embodiment;

FIG. 18 is a top view of a tank with the intake of FIG. 17A or FIG. 17B;

FIG. 19 depicts an immersion cooling system with two tanks, in accordance with an embodiment; and

FIG. 20 is a top plan view of the intakes of the immersion cooling system of FIG. 19.

These drawings depict example embodiments for illustrative purposes, and variations, alternative configurations, alternative components and modifications may be made to these example embodiments.

### DETAILED DESCRIPTION

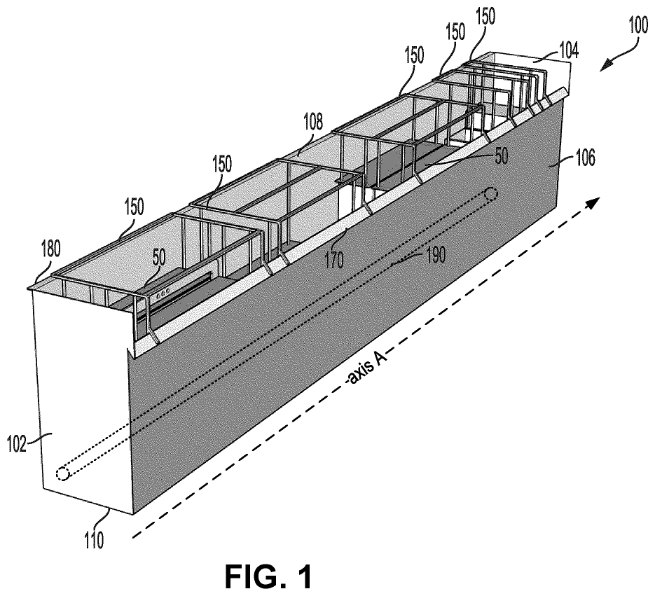

FIG. 1 depicts a tank 100 of an immersion cooling system for electronic devices, in accordance with an embodiment.

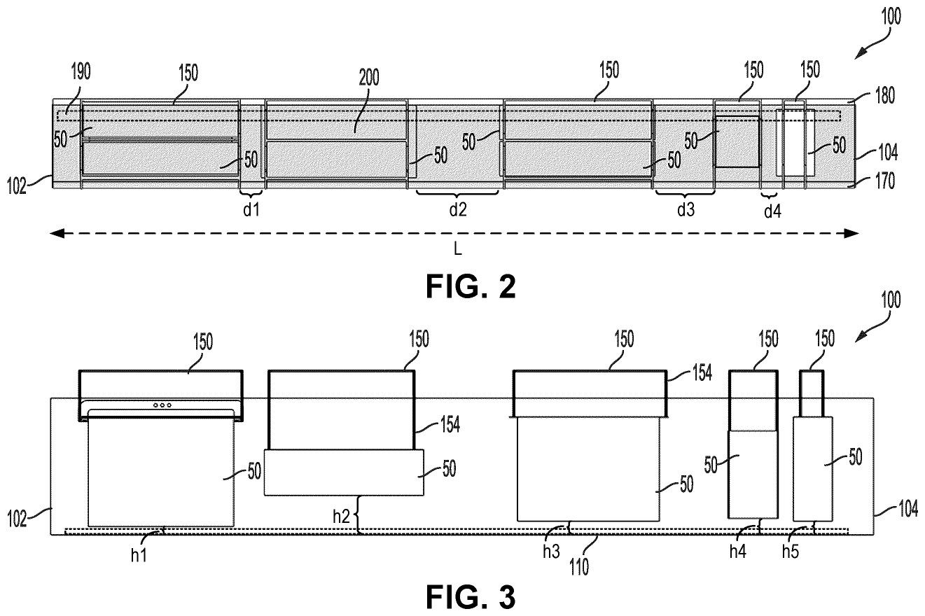

Tank 100 includes side walls 106 and 108 extending along a longitudinal axis A of tank 100. Side walls 106 and 108 are terminated at one end by an end wall 102, and at an opposite end by an end wall 104. Side walls 106 and 108 are substantially parallel to one another; end walls 102 and 104 are substantially parallel to one another. Together, side walls 106 and 108 and end walls 102 and 104, and floor 110 define a liquid-sealed container to contain a cooling liquid 200 (FIG. 2) and receive a plurality of electronic devices 50 immersed in the cooling liquid. The direction of longitudinal axis A will be referred to as a horizontal direction herein.

In the depicted embodiment, tank 100 has an open top to permit convenient addition and removal of electronic devices 50. In some embodiments, the top of tank 100 may be covered by a suitable cover, e.g., to provide protection of tank contents from debris and other unwanted elements. In some embodiments, the cover may provide a working surface and/or walking surface atop tank 100.

Tank 100 includes an intake 190 disposed proximate floor 110 at the bottom of tank 100. Intake 190 dispenses cooling liquid 200 into the bottom of tank 100. Intake 190 extends proximate side wall 108 along longitudinal axis A.

Tank 100 includes an outtake defined by a lip 170 extending horizontally along the top of side wall 106. During operation, as cooling liquid 200 is dispensed into tank 100 via intake 190, cooling liquid 200 flows upwards past (e.g., around and through) immersed electronic devices 50, and flows out of tank 100 over lip 170. In this way, lip 170 defines a maximum fill height of cooling liquid 200 within tank 100. Each of side wall 108, and rear walls 102 and 104 have a height extending higher than this maximum fill height, to prevent cooling liquid 200 from spilling over these respective walls.

Cooling liquid 200 that flows out of tank 100 over lip 170 flows to a downstream heat exchange system (not shown) that removes heat from cooling liquid 200, and to a reservoir to be later pumped back into tank 100.

Tank 100 includes one or more mounts for mounting electronic devices to be immersed in cooling liquid 200. In the depicted embodiment, such mounts are provided by a plurality of hangers 150 which are removably mountable proximate a top of tank 100. As depicted, electronic devices 50 are removably mountable to a plurality of hangers 150. Each hanger 150 is configured to slidably rest on top of side walls 106 and 108. When hanger 150 is in this resting position, an electronic device 50 mounted thereto is suspended in tank 100 and immersed in cooling liquid 200.

As shown in FIG. 2, a hanger 150 may be rested to place a mounted electronic device 50 at a desired horizontal position along length L of tank 100. This horizontal position may be adjusted by sliding hanger 150 along the respective tops of side walls 106 and 108. Conveniently, this horizontal position may be dynamically adjusted during operation of electronic devices 50. Since hanger 150 slidably rests on the tops of side walls 106 and 108, there is no need to unfasten any fasteners to change the horizontal position of a mounted electronic device 50.

The horizontal positions of electronic devices 50 may create variable horizontal spacing (e.g., d1, d2, d3, d4) between electronic devices 50. Such horizontal spacing may be selected, for example, based on an amount of heat generated by each electronic device 50, the number of electronic devices 50 to be accommodated in tank 100, the need to avoid interference (e.g., radiofrequency interference) between electronic devices 50, or other criteria.

Importantly, in the depicted embodiment, the horizontal spacing between electronic devices 50 and the horizontal position of electronic devices 50 are not constrained by mechanical features of tank 100 such as rails, slots, guides, spacers, or the like. Similarly, the horizontal size (i.e., width) of each hanger 150 may vary, to accommodate electronic devices 50 of various sizes, without such constraints.

As shown in FIG. 3, each hanger 150 extends into tank 100 to suspend a mounted electronic device 50 at a desired vertical position in tank 100. In particular, hanger 150 may have arms 154 of varying lengths to suspend electronic device 50 at the desired vertical position. For example, the vertical positions of electronic devices 50 may create variable vertical spacing between (e.g., h1, h2, h3, h4, and h5) between the respective bottoms of electronic devices 50 and floor 110. Similarly, the vertical positions of electronic devices 50 may create variable vertical spacing between the respective tops of electronic devices 50 and the fill height of cooling liquid 200. Such vertical spacing may be selected, for example, based on a desired operating temperature of an electronic device 50, an amount of heat generated by an electronic device 50, thermal properties of cooling liquid 200, and rate of flow of cooling liquid 200, or other criteria.

Importantly, in the depicted embodiment, the vertical position of electronic devices 50 is not constrained by mechanical features of tank 100 such as rails, slots, guides, spacers, or the like. Similarly, the length of each hanger 150 (e.g., length of arm 154) may vary, to accommodate electronic devices 50 of various sizes.

During operation, cooling liquid 200 is dispensed into the bottom of tank 100 via intake 190 at an initially cooler temperature. As cooling liquid 200 flows upward towards the outtake provided by lip 170, heat is transferred from electronic devices 50 into cooling liquid 200. As such, a temperature gradient may be formed whereby relatively cooler temperatures are at the bottom of tank 100 and relatively warmer temperatures are at the top of tank 100. The vertical position of a given electronic device 50 may be selected to be placed along this gradient based on an optimal working temperature range of that electronic device 50. For example, in some embodiments, the temperature gradient in tank 100 may range from approximately 20° C. and 80° C., where the lower range is the temperature of cooling liquid 200 when dispensed into tank 100. In some embodiments, the temperature gradient in tank 100 may range from approximately 30° C. to 60° C., again where the lower range is the temperature of cooling liquid 200 when dispensed into tank 100.

In the depicted embodiment, electronic devices 50 are suspended above floor 110. For example, electronic devices 50 may be suspended a few centimeters (e.g., 5-10 cm) above floor 110. Suspending electronic devices 50 in this way places the devices above intake 190.

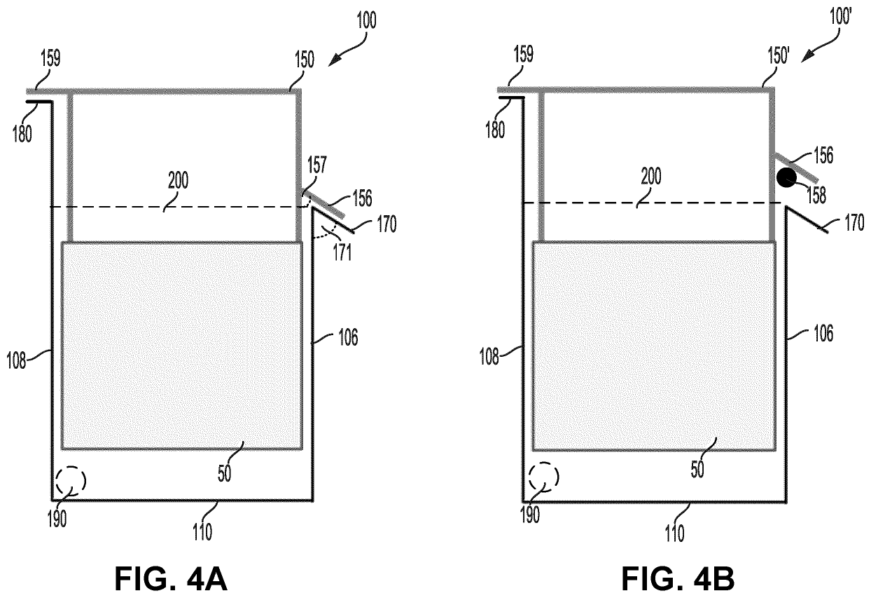

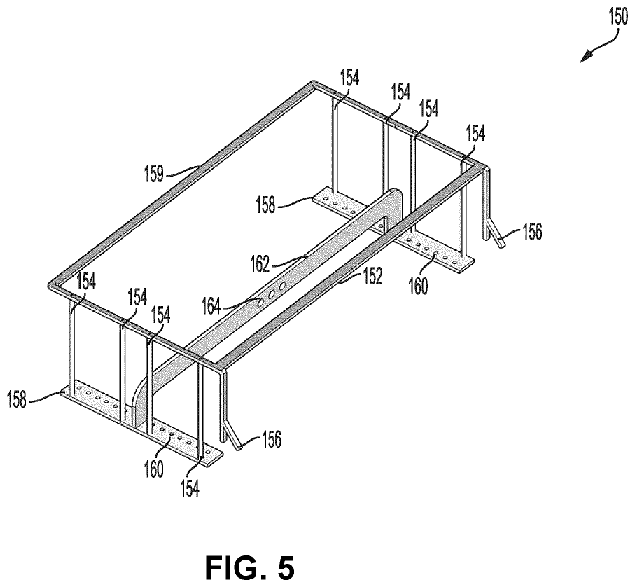

As shown in FIG. 4A, lip 170 providing an outtake of tank 100 slopes downward away from side wall 106. This slope facilitates smooth flow of cooling liquid 200 out of tank 100 and may minimize frothing of cooling liquid 200. In some embodiments, an angle 171 of this slope may be between approximately 30-70 degrees. In some embodiments, angle 171 may be between approximately 40-60 degrees. Hanger 150 includes two mounts 156 (as best seen in FIG. 5) for resting on lip 170. The number of mounts 156 may vary from embodiment to embodiment, and may be fewer or greater.

In the depicted embodiment, each mount 156 extends at an angle 157 to form a v-shape for engaging the slope of lip 170. So, for example, angle 157 may be selected to substantially match angle 171. In other embodiments, mount 156 may extend substantially perpendicularly (e.g., so that angle 171 is approximately 90 degrees).

Hanger 150 also includes a mount 159 for resting on the top of side wall 108. The top of side wall 108 may include a substantially flat lip 180 to support mount 159. Lip 180 may extend the length of side wall 108.

FIG. 4B shows a tank 100′, in accordance with another embodiment. Tank 100′ includes a rail 158 extending horizontally along the top of side wall 106 between end walls 102 and 104. Rail 158 is substantially parallel to lip 170. Rail 158 is disposed to be above lip 170. Hanger 150′ includes a mount 156 for slidably resting on rail 158, above lip 170. When hanger 150′ is resting on rail 158, the flow of cooling liquid 200 over lip 170 avoids hanger 150′. Mount 156 is disposed higher on hanger 150′ compared to hanger 150. Hanger 150′ is otherwise substantially similar to hanger 150. Aside from the addition of rail 158, tank 100′ is substantially similar to tank 100.

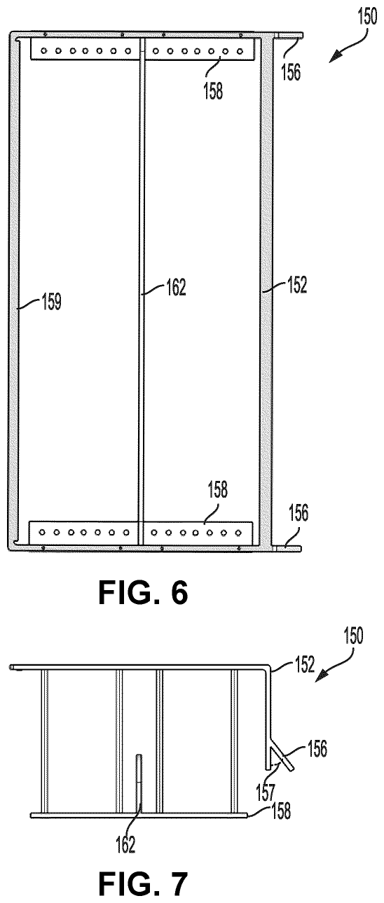

FIG. 5, FIG. 6, and FIG. 7 each depicts a hanger 150, in accordance with an embodiment. Hanger 150 includes a top frame 152 that is substantially rectangular in shape. In some embodiments, top frame 152 may be substantially square in shape. A pair of mounts 156 extends downward from a front of frame 152 for resting on lip 170 of tank 100. Top frame 152 includes a further mount in the form of rear rail 159 for resting on lip 180 of tank 100. As shown, rear rail 159 is disposed higher than mounts 156, so that each meets the respective heights of lip 180 and lip 170.

A plurality of arms 154 extend between top frame 152 and a pair of brackets 158 at each side of hanger 150. Brackets 158 allow one or more electronic devices 50 to be mounted to the bottom of hanger 150 and extend below hanger 150. Each bracket 158 includes a plurality of fastener holes 160 for removably fastening one or more electronic devices 50. Fastener holes 160 may be provided along the length of bracket 158 to accommodate different fastening locations for different electronic devices 50. Fastener holes 160 may be, for example, pre-threaded screw holes.

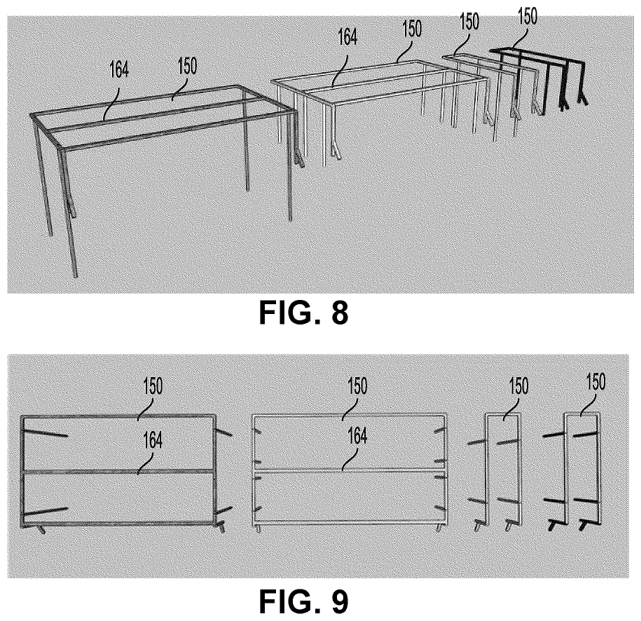

In the depicted embodiment, hanger 150 includes four arms 154 on each of its left and right sides. However, the number of arms 154 could be greater or fewer. For example, in some embodiment, hanger 150 includes two arms 154 on each of its left and right sides (FIG. 8 and FIG. 9).

In some embodiments, brackets 158 can be omitted, and one or more electronic devices 50 can be fastened directly to the ends of arms 154. In such embodiments, one or more fastener holes may be provided at the end of each arm 154.

A grip 162 extends between the left and right sides of hanger 150 to allow hanger 150 to be handled or otherwise manipulated by a user, e.g., to be lowered into a resting position atop of tank 100, pulled from its resting position atop of tank 100, or be pulled into a desired horizontal position along tank 100. As depicted, grip 162 includes a plurality of finger holes 164 to improve a user's grip.

In some embodiments, grip 162 can be omitted, and hanger 150 can be manipulated via another portion such as top frame 152.

When hanger 150 is in a resting position on the tops of side walls 106 and 108, a portion of each arm 154 extend into cooling liquid 200 to immerse electronic device(s) 50 therein. Portions of hanger 150 (e.g., top frame 152 and grip 162) remain above the surface of the cooling liquid 200. This facilitates easy manipulation of hanger 150, e.g., to adjust its position without requiring a user to sink a hand into cooling liquid 200.

Various sizes and configurations of hangers 150 may be provided, as shown in FIG. 8 and FIG. 9. Hangers 150 may differ from one another in width to accommodate electronic devices 50 of various widths. Hangers 150 may also differ from one another in the length of their arms 154, to accommodate electronic devices 50 of various heights and to place such electronic devices 50 at various desired vertical positions within tank 100. Larger sizes of hangers 150 may include structural support members (e.g., member 164) to improve structural integrity when under mechanical load of mounted electronic devices 50.

Hangers 150 may also differ from one another in the number of electronic devices 50 mountable thereto. For example, some hangers 150 may be sized to accommodate a single electronic device 50. Meanwhile, some hangers 150 may be sized to accommodate a greater number of devices, e.g., two electronic devices 50, or an even greater number of electronic devices 50. In some embodiments, where hangers 150 are expected to be manually manipulable by a single user, the number of mountable electronic devices 50 may be constrained so that the overall size and mass of a hanger 150 and mounted electronic devices 50 are within the ability of a single user to manipulate.

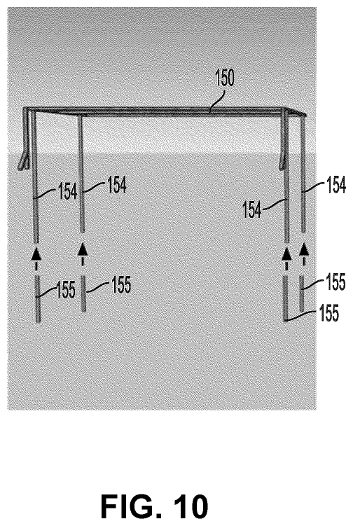

In some embodiments, a hanger 150 may have an adjustable width and/or an adjustable height. As shown in FIG. 10, in one embodiment, the length of each arm 154 can be increased by affixing an extender 155. Extender 155 may provided pre-threaded portion for inserting into and affixing to arm 154. In some embodiments, arms 154 may telescope to provide a variable length.

Each electronic device 50 is a data storage device, a data processing device, a data networking device, another type of computing device, or any other type of electronic device that generates waste heat during operation. For example, electronic device 50 may be a cloud computing device, a web server, an image/video rendering server, a cryptocurrency mining device, or the like. In one specific example, cryptocurrency mining devices may include, for example, ASIC-based miners such as a Bitmain™ Antminer™ S19, or MicroBT™ Whatsminer™ M30S, or the like. Importantly, the flexible configuration of hangers 150 disclosed herein allows tank 100 to accommodate a combination of different electronic devices 50, having different operating temperature requirements, and/or having different dimensions.

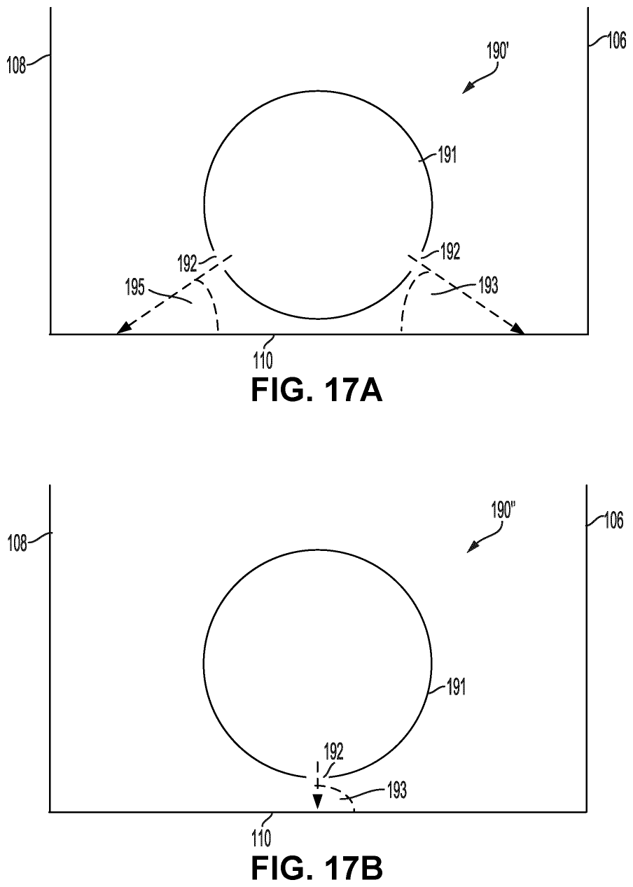

Electronic devices 50 may be wired for network access. Tank 100 may include suitable interfaces, ports, and openings, for network and/or power connections for electronic devices. For example, openings may be provided in a wall of tank 100 to provide for passage of network and/or power connections. Such openings may include, for example, openings 178 in one or both of side walls 106 and 108, which are provided above the fill height of cooling liquid 200 (FIG. 17). Such openings may, for example, prevent interference between such network and/or power connections and a cover placed over tank 100.

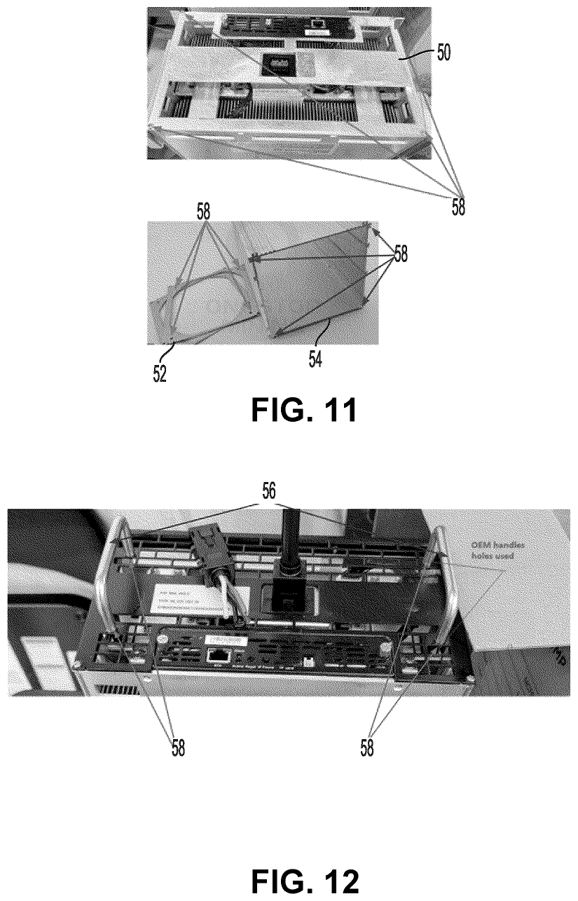

FIG. 11 depicts an example electronic device 50 mountable to a hanger 150, in accordance with an embodiment. The depicted electronic device 50 is a conventional OEM computing device with an OEM faceplate 52 and an OEM chassis 54. Faceplates 52 can be unscrewed from chassis 54 to expose fastener holes 58 at the corners of chassis 54.

FIG. 12 depicts another electronic device 50 mountable to a hanger 150, in accordance with an embodiment. The depicted electronic device 50 is a conventional OEM computing device 50 with OEM handles 56. Handles 56 can be unscrewed from the computing device to expose fastener holes 58.

Fastener holes 58 depicted in FIG. 11 and FIG. 12 may be, for example, pre-threaded screw holes. Such fastener holes 58 may be repurposed for mounting electronic device 50 to hanger 150.

Chassis 54 of electronic device 50 may be fastened to hanger 150 using screws through fastener holes 58 and corresponding fastener holes 160 on bracket 158 of hanger 150. In some embodiments, chassis 54 may be fastened to hanger 150 using screws through fastener holes 58 and fastener holes at the ends of arms 154 of hanger 150.

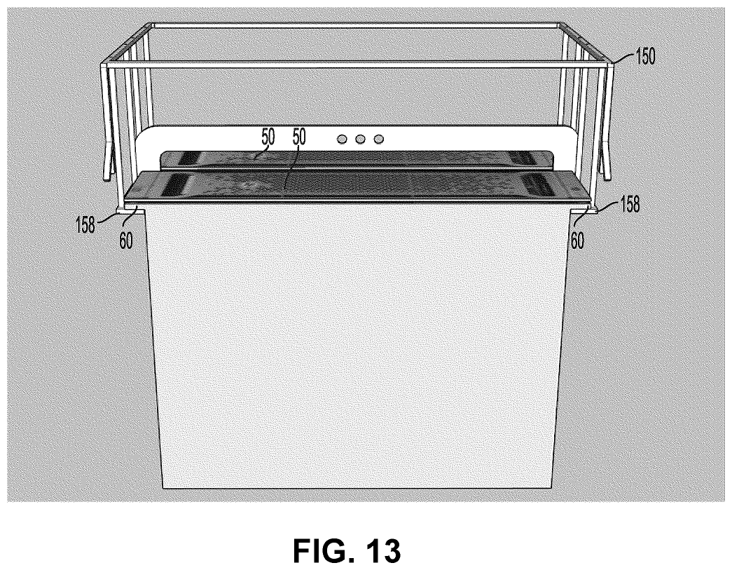

FIG. 13 depicts two electronic device 50 mounted to a hanger 150, in accordance with an embodiment. As depicted, each of these electronic devices 50 may be slid onto hanger 150 such that a lip or edge of the electronic device 50 rests on top of brackets 158 and be cradled thereby. In this embodiment, no fasteners need to be used to attach the electronic devices to hanger 150.

Various other ways of mounting electronic devices 50 to hangers 150 will be readily apparent to persons of ordinary skill in the art, e.g., clamps, bolts, magnets, etc.

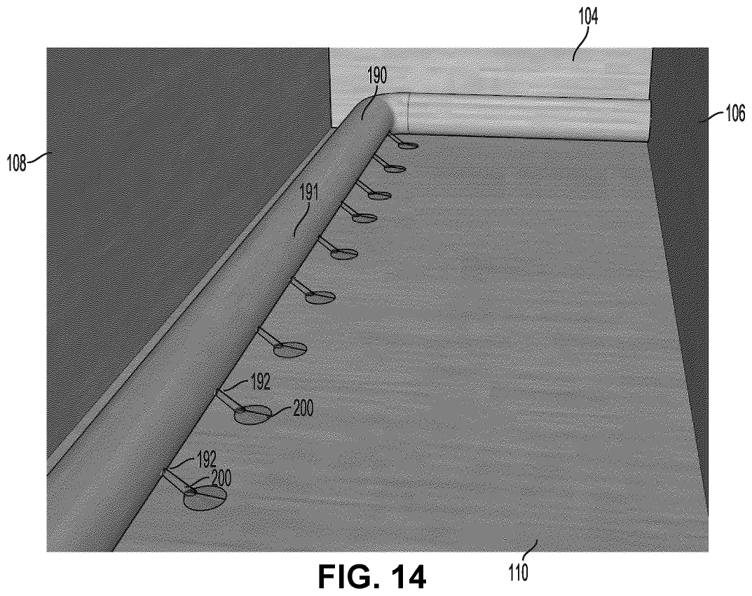

FIG. 14 shows intake 190 dispensing cooling liquid 200 into tank 100, in accordance with an embodiment. To illustrate the angle at which cooling liquid 200 is dispensed, tank 100 is shown in an initially empty state.

Intake 190 includes a pipe 191 that extends between end walls 102 and 104. Pipe 191 includes a first end proximate end wall 102 and a second end proximate end wall 104. Pipe 191 extends proximate a corner of tank 100, e.g., proximate floor 110 and side wall 108, and extends parallel to side wall 108.

In some embodiments, pipe 191 has a diameter between 5-50 mm.

In some embodiments, intake 190 dispenses cooling liquid 200 into tank 100 via pipe 191 at a rate between 50-200 gallons/minute.

As depicted, pipe 191 includes a plurality of inlets 192, each providing an opening (e.g., a hole, slit, or the like) through which cooling liquid 200 can be urged under pressure into tank 100. Inlets 192 are disposed to substantially span length L of tank 100 (FIG. 2). Inlets 192 are substantially evenly spaced from one another.

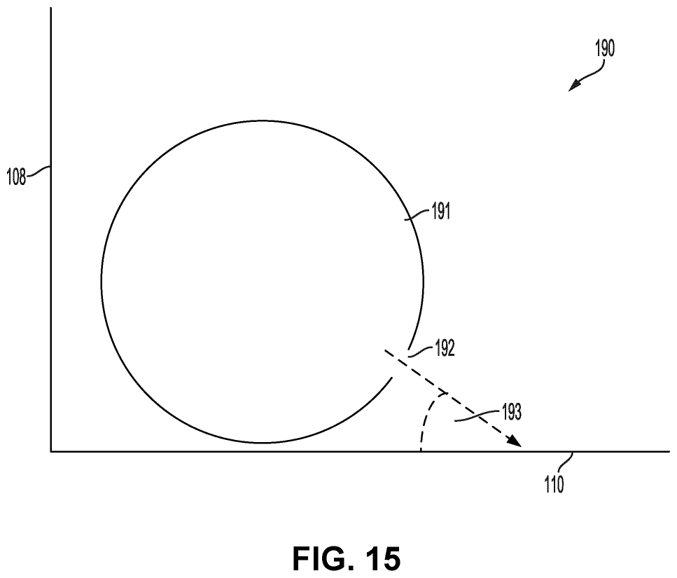

As depicted in FIG. 15, each inlet 192 is angled to provide a pressurized stream of cooling liquid 200 at a downward angle 193 towards the bottom (e.g., floor 110) of tank 100. The stream of cooling liquid 200 is substantially parallel to at least a portion of one or both of end walls 102 and 104. The streams of cooling liquid 200 impact floor 110 and spread across the bottom of tank 100 substantially towards side wall 106. In some embodiments, angle 193 is between approximately 30 and 60 degrees. In some embodiments, angle 193 is between approximately 40 and 50 degrees. In some embodiments, angle 193 is 90 degrees such that the stream of cooling liquid 200 is directed straight down towards the bottom of tank 100.

In some embodiments, inlets 192 are spaced apart by approximate 5-10 centimeters. In some embodiments, inlets 192 are spaced apart by approximately 10-20 centimeters. In some embodiments, inlets 192 are spaced apart so that multiple inlets 192 are provided below each potential horizontal position of an electronic device 50.

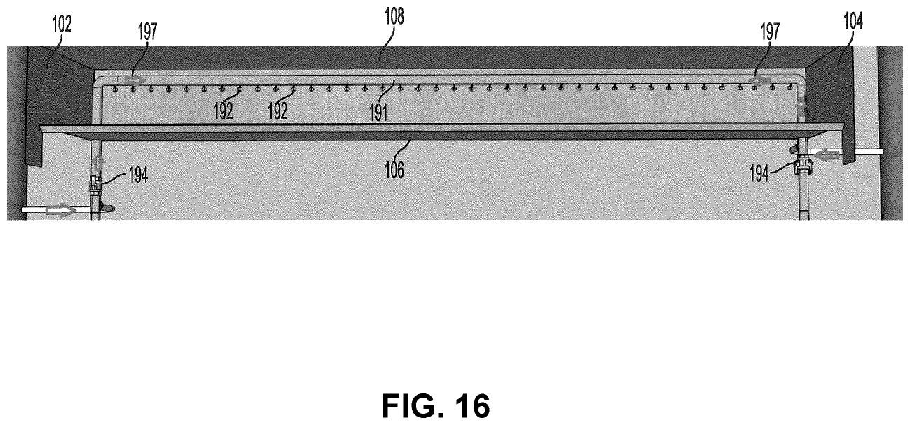

As shown in FIG. 16, thirty-nine inlets 192 are provided in tank 100. In other embodiments, the number of inlets 192 may vary, e.g., in dependence on the length L of tank 100. For example, there may be a fewer or greater number of inlets 192. The number of inlets may be selected based on, at least in part, the total flow rate of intake 190. In some embodiments, a single inlet 192 may be provided in tank 100.

Pipe 191 is in fluid communication with two intake feeds 194 providing pressurized cooling liquid 200 at each end of pipe 191. Intake feeds 194 are in turn connected to upstream distribution pipes, which are in turn in fluid communication with one or more pumps that urge cooling liquid 200 to flow from a reservoir towards intake feeds 194.

Cooling liquid 200 from the two intake feeds 194 flow via two respective flow paths into pipe 191 and opposing ends of pipe 191, and converge in pipe 191 as shown by arrows 197 (FIG. 16). This convergence in pipe 191 causes pressure equalization along pipe 191, which in turn causes cooling liquid 200 to be urged through each of inlets 192 into tank 100 at substantially equal flow rates.

As noted above, the downward angle of inlets 192 causes streams of cooling liquid 200 to impact floor 110 and spread across the bottom of tank 100. In some embodiments, because newly dispensed cooling liquid 200 is relatively cooler, it flows across the bottom of tank 100 via liquid motion effected by natural convection. Once in tank 100, warmer cooling liquid 200 moves upwards creating the temperature gradient noted above, which may also be referred to as temperature stratification.

In some embodiments, due to the combined effects of buoyancy and momentum, cooling liquid 200 dispensed from an inlet 192 moves outward radially therefrom. In such embodiments, cooling liquid 200 dispensed from each of the inlets 192 spreads out in this radial manner, and may spread to cover substantially the entire floor 110 of tank 100. In particular, when cooling liquid 200 is dispensed from a downward facing inlet 192 proximate a bottom of tank 100, it is cooler and thus denser than cooling liquid 200 already in tank 100, and thus initially sinks towards floor 110 of tank 100. Cooler cooling liquid 200 being dispensed concurrently from multiple inlets 192 creates multiple localized pools of cooler cooling liquid 200, which may expand and spread out radially to cover substantially the entire floor 110 of tank 100. As the cooler cooling liquid 200 mixes with warmer cooling liquid 200 surrounding it, it creates a more uniform temperature distribution across the bottom of tank 100. Such uniform temperature distribution is desirable for cooling devices 50 evenly, and may also help avoid hot spots within tank 100 which could impair computing device performance and efficiency.

In some embodiments, the downward angle of inlets 192 facilitates substantially even flow of cooling liquid 200 throughout tank 100 and substantially even cooling across the width and length of tank 100. This in turn provides substantially even cooling to each potential location of an electronic device 50 in tank 100. In some cases, this provides substantially even cooling to portions of each electronic device 50 in tank 100, e.g., so that each component such as particular chips receives substantially similar cooling).

Conveniently, in some embodiments, the use of perforated plates or other mechanical features to direct liquid flow towards immersed devices may be avoided. This also avoids certain drawbacks or undesirable temperature distortions attributable to perforated plates and similar mechanical features such as, for example, requiring immersed devices to be placed at specific locations defined by the plates, decrease in cooling evenness across devices based on location relative to the plates, decrease in cooling evenness across portions of devices based on location relative to the plates, constraints on the types of devices that can be cooled based on the shapes of the plates, and so on.

In the depicted embodiments, electronic devices 50 are suspended above floor 110. This suspension ensures that electronic devices 50 do not block the streams of cooling liquid 200 entering tank 200 from impacting floor 110. Further, this suspension ensures that electronic devices 50 do not impede the spread of cooler cooling liquid 200 across the bottom of tank 100, e.g., due to natural convection.

FIG. 17A depicts an intake 190′ for dispensing cooling liquid 200 into tank 100, in accordance with another embodiment. Intake 190′ may be used in place of intake 190.

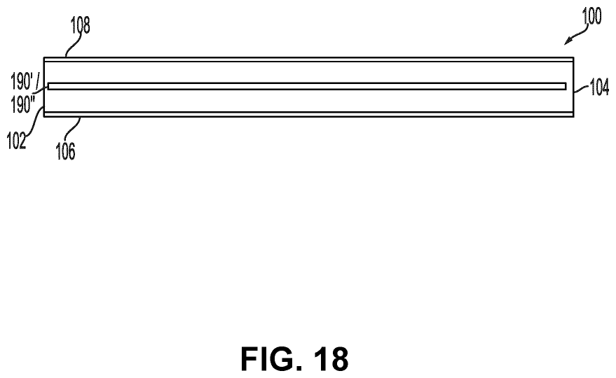

As depicted, intake 190′includes a pipe 191 that is disposed centrally along the bottom of the tank 100. In this way, intake 190′ differs from intake 190, in which pipe 191 is disposed proximate a side wall of tank 100 (e.g., proximate side wall 108 as depicted in FIG. 14, or alternatively, proximate side wall 106). As best seen in FIG. 18, pipe 191 may be disposed to extend along the length of tank 100 at the middle of tank 100, e.g., approximately equidistant from side walls 106 and 108.

Referring again to FIG. 17A, pipe 191 includes two sets of inlets 192: a first set oriented towards side wall 106, and a second set oriented towards side wall 108. The first set of inlets 192 may be angled to each provide a pressurized stream of cooling liquid 200 at a downward angle 193 towards the bottom (e.g., floor 110) of tank 100. These streams of cooling liquid 200 impact floor 100 and spread across the bottom of tank 100, substantially towards side wall 106. On the other side of pipe 191, the second set of inlets 192 may be angled to each provide a pressurized stream of cooling liquid 200 at a downward angle 195 towards the bottom (e.g., floor 110) of tank 100. These stream of cooling liquid 200 impact floor 100 and spread across the bottom of tank 100, substantially towards side wall 108. Angle 193 may be an angle as described above. In some embodiments, angle 195 may be a similar or the same magnitude as angle 193. In some embodiments, angle 193 and angle 195 may differ in magnitude.

In intake 190′, the sizing and spacing of inlets 192 may be configured to provide a rate and pressure for dispensing cooling liquid 200 similar to intake 190.

FIG. 17B shows an intake 190″ for dispensing cooling liquid 200 into tank 100, in accordance with another embodiment. Intake 190″ may be used in place of intake 190.

Similar to intake 190′, intake 190″ includes a pipe 191 that is disposed centrally along the bottom of the tank 100. As best seen in FIG. 18, pipe 191 may be disposed to extend along the length of tank 100, approximately equidistant from side walls 106 and 108.

As depicted, in intake 190″, downward angle 193 of inlet 192 is approximate 90 degrees such that the stream of cooling liquid 200 is directed approximately straight down towards the bottom of tank 100. In some embodiments, the stream of cooling liquid may be substantially parallel to at least a portion of one or both of side walls 106 and 108. In some embodiments, the stream of cooling liquid may be substantially perpendicular to at least a portion of the bottom (e.g., floor 110) of tank 100. In embodiments of intake 190″, inlet 192 may be disposed at the center of a bottom of pipe 191. During operation, the streams of cooling liquid 200 impact floor 110 and spread across the bottom of tank 100, substantially towards side walls 106 and 108.

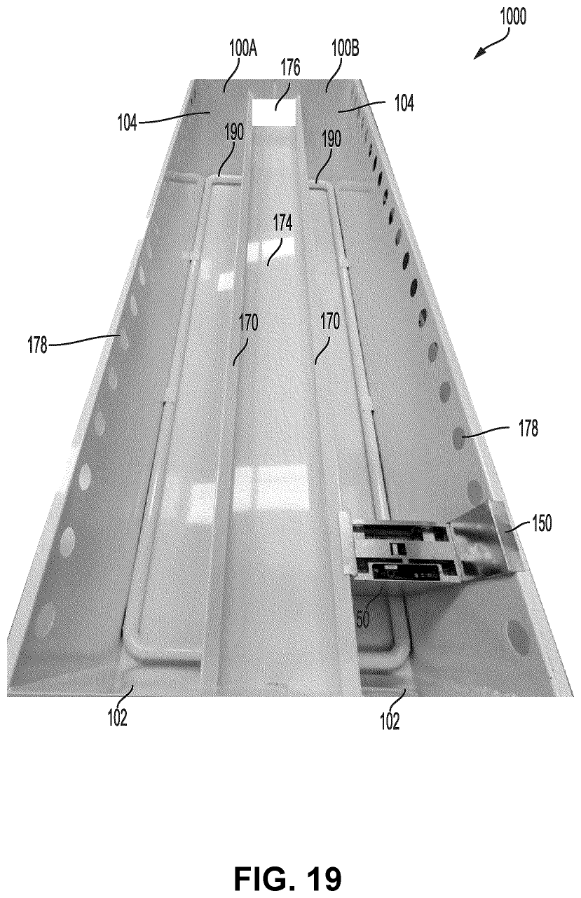

FIG. 19 depicts an immersion cooling system 1000, in accordance with an embodiment. As depicted, immersion cooling system 1000 includes two tanks 100, identified as tank 100A and tank 100B. The two tanks 100 are oriented such that lip 170 of tank 100A and lip 170 of tank 100B are substantially parallel and meet at a trough 174 extending between the tanks. Tanks 100A and 100B are substantially the same length.

Trough 174 receives cooling liquid 200 flowing over lip 170 of tank 100A and cooling liquid 200 flowing over lip 170 of tank 100B. Trough 174 slopes in a direction substantially parallel to these lips 170 towards an opening 176 in common end wall 104. Cooling liquid flows through opening 176 flows to a downstream heat exchange system (not shown) that removes heat from cooling liquid 200, and to a reservoir to be later pumped back into system 1000.

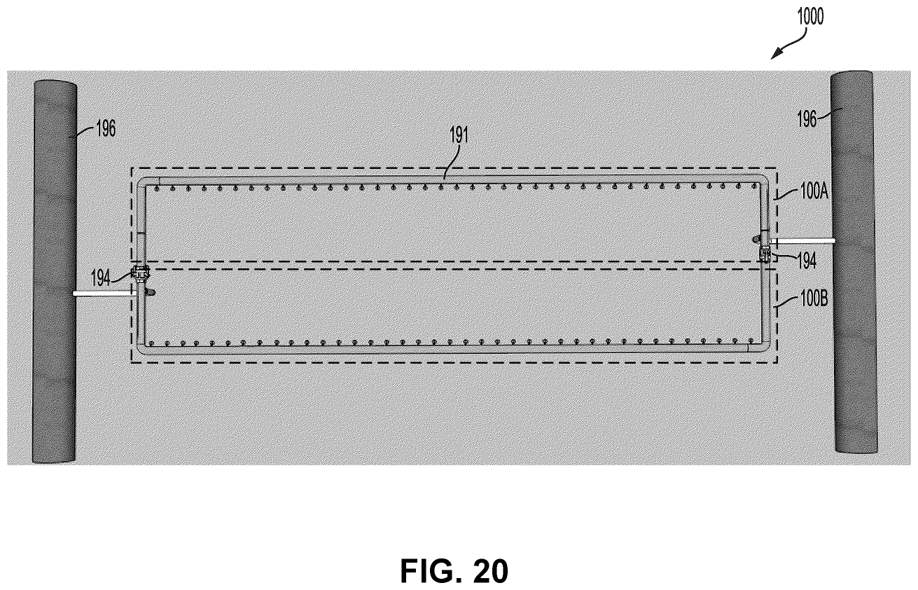

As shown in FIG. 20, intake 190 of tank 100A and intake 190 of tank 100B include a pipe that forms a loop extending through both tanks 100A and 100B. Pressurized cooling liquid 200 is provided to this loop via the two intake feeds 194. In other words, tanks 100A and 100B share intake feeds 194, which provide two flow paths of cooling liquid 200 into intake 190 of each tank.

During operation, if either tank 100A or tank 100B is not operational, then one half of the loop can be sealed against flow of cooling liquid 200. Cooling liquid 200 would then only flow in an unsealed half of the loop.

Tank 100 may be sized to fit a plurality of electronic devices 50. In the depicted embodiments, tank 100 is sized to provide a width that accommodates a width of a hanger 150 that rests on top of side walls 106 and 108, where the width of hanger 150 is in turn sized to fit one or more electronic devices 50. In the depicted embodiments, tank 100 is sized to provide a height (or depth) to accommodate a height of electronic devices 50 and to allow placement at a desired vertical position. In the depicted embodiments, tank 100 is sized to provide a length L (FIG. 2) to accommodate a plurality of electronic devices 50. Tank 100 may be sized to accommodate any number electronic devices 50 along length L (e.g., 10, 20, 50, or more). In one example embodiment, tank 100 is approximately 1 meter in width, approximately 3 meters in length, and approximately 1 meter in height (depth).

Tank 100 is formed of metals (e.g., stainless steel, aluminum, or the like) and/or other materials (e.g., plastics, resins, or the like) having suitable strength and stiffness to support the mechanical load of both cooling liquid 200 and suspended electronic devices 50. Tank 100 is formed of materials (or materials having suitable coatings) to resist corrosion or damage caused by cooling liquid 200. Hangers 150 and pipe 191 may each be formed of similar materials.

In some embodiments, an electronic device 50 may be suspended in tank 100 by placing it on a lip, rail, shelf, or other protuberance extending from a side wall of tank 100. In some embodiments, an electronic device 50 may be suspended in tank 100 by placing it on a post, beam, or other protuberance extending from a bottom surface of tank 100. In each of such embodiments, hangers 150 may be omitted.

Cooling liquid 200 is a conventional dielectric liquid such as Shell S3X dielectric liquid. In some embodiments, another liquid that is thermally conductive yet electrically substantially non-conductive may be used. In some embodiments, the liquid is also non-flammable. In some embodiments, a glycol such as ethylene glycol or propylene glycol, or a solution thereof, may be used. In some embodiments, a polyalphaolefin or similar synthetic oil may be used. In various embodiments, various suitable synthetic or natural hydrocarbons, or combinations thereof may be used. In some embodiments, deionized water may be used.

Of course, the above described embodiments are intended to be illustrative only and in no way limiting. The described embodiments are susceptible to many modifications of form, arrangement of parts, details and order of operation. The disclosure is intended to encompass all such modification within its scope, as defined by the claims.

1. A tank for immersion cooling of electronic devices, the tank comprising:
an intake disposed proximate a bottom surface of the tank, the intake including at least one inlet for dispensing cooling liquid into the tank; and
an outtake defined by a lip extending proximate a top wall of the tank, whereby the cooling liquid exits the tank by flowing over the lip; and
wherein the at least one inlet is oriented downwardly such that the cooling liquid dispensed therethrough initially flows downward towards the bottom surface of the tank before flowing upward past at least one electronic device disposed in the tank.

2. The tank of claim 1, wherein the intake is configured to provide a pressurized stream of cooling liquid at a downward angle through the inlet.

3. The tank of claim 1, wherein the downward angle is between approximately 20-90 degrees relative to the bottom surface of the tank.

4. The tank of claim 3, wherein the downward angle is between approximately 30-70 degrees relative to a bottom surface of the tank.

5. The tank of claim 3, wherein the downward angle is approximately 90 degrees relative to the bottom surface of the tank.

6. The tank of claim 1, wherein the cooling liquid dispensed through the at least one inlet spreads across at least a portion of the bottom surface of the tank.

7. The tank of claim 1, wherein the at least one inlet includes a plurality of inlets.

8. The tank of claim 7, wherein the plurality of inlets are substantially evenly spaced from one another.

9. The tank of claim 7, wherein the intake is configured to cause the cooling liquid to be dispensed through each of the plurality of inlets with substantially similar pressure.

10. The tank of claim 1, wherein the intake includes a first end and a second end, the ends proximate respective end walls of the tank.

11. The tank of claim 10, wherein the at least one inlet is oriented to dispense the cooling liquid in a direction parallel to at least one of the end walls.

12. The tank of claim 10, wherein each of the first end and the second end is in fluid communication with an intake feed that urges the cooling liquid into that end.

13. The tank of claim 10, wherein the cooling liquid urged into the first end of the intake converges with the cooling liquid urged into the second end of the intake.

14. The tank of claim 1, wherein the tank is configured to suspend the at least one electronic device above the bottom surface of the tank.

15. An immersion cooling system for electronic devices, the system comprising:
a first tank as claimed in claim 1,
a second tank as claimed in claim 1,
wherein the first and second tanks are oriented such that the lip of the first tank and the lip of the second tank are substantially parallel and meet at a trough extending between the tanks, and the cooling liquid flowing over the lips is received in the trough.

16. The immersion cooling system of claim 15, wherein the trough slopes in a direction substantially parallel to the lips of the first and second tanks.

17. A method for immersion cooling of electronic devices, the method comprising:
suspending at least one electronic device above a bottom surface of a tank for containing cooling fluid; and
dispensing the cooling fluid into the tank from an intake disposed proximate the bottom surface of the tank; and
wherein the cooling fluid is dispensed downwardly such that the cooling liquid flows towards the bottom surface of the tank before flowing upward past the at least one electrical device and out of the tank.

18. The method of claim 17, further comprising sliding the at least one electronic device to adjust its horizontal position in the tank without removing the at least one electronic device from the tank.

19.-31. (canceled)
